(19) United States
(12) Patent Application Publication
(10) Pub. No.: US 2019/0014684 A1
(43) Pub. Date: Jan. 10, 2019

(54) HEAT DISSIPATION SYSTEM AND ELECTRONIC DEVICE

(71) Applicants: Inventec (Pudong) Technology Corporation, Shanghai City (CN); Inventec Corporation, Taipei City (TW)

(72) Inventor: MENG-LUNG CHIANG, Taipei City (TW)

(21) Appl. No.: 15/863,962

(22) Filed: Jan. 7, 2018

(30) Foreign Application Priority Data
Jul. 4, 2017 (CN) 201710536599.4

(51) Int. Cl. H05K 7/20

(52) U.S. Cl. CPC H05K 7/20154

(57) ABSTRACT

An electronic device includes a casing, an electronic module, a heat sink, an airflow generator, and an ion generator. The casing has an accommodating space and an air inlet is connected to the accommodating space. The electronic module is located in the accommodating space. The heat sink is located in the accommodating space, and the heat sink is connected to the electronic module. The airflow generator located in the accommodating space has an air inlet opening and an air outlet opening. The air inlet opening is connected to the air inlet. The airflow generator is used to generate air flow to the heat sink along an air flow path through the air outlet opening. The ion generator is located in an air flow path of the air flow between the heat sink and the airflow generator in order to produce ions.

### CROSS-REFERENCE TO RELATED APPLICATIONS

This non-provisional application claims priority under 35 U.S.C. § 119(a) on Patent Application No(s). 201710536599.4 filed in China on Jul. 4, 2017 the entire contents of which are hereby incorporated by reference.

### BACKGROUND OF THE INVENTION

### Technical Field of the Invention

The disclosure relates to a heat dissipation system and an electronic device having the same, more particularly to a heat dissipation system including an ion generator and an electronic device having the same.

### Description of the Related Art

In recent years, as electronic technology progresses, the computational speed of the electronic components inside an electronic device is constantly enhancing, but this enhancement consumes more electricity and generates more internal heat of the electronic component. In order to prevent failure of the electronic component due to overheat, the electronic device requires sufficient heat dissipation to operate at a desired temperature.

The cooperation of a fan and a heat sink is a common way to actively dissipate heat generated by the electronic components. For example, the heat sink is disposed on a central processing unit (CPU), and the fan generates an air flow to the heat sink to take the heat generated by the CPU away to decrease the temperature of the CPU.

### SUMMARY OF THE INVENTION

One embodiment of the disclosure provides an electronic device includes a casing, an electronic module, a heat sink, an airflow generator, and an ion generator. The casing has an accommodating space and an air inlet is connected to the accommodating space. The electronic module is located in the accommodating space. The heat sink is located in the accommodating space, and the heat sink is connected to the electronic module. The airflow generator located in the accommodating space has an air inlet opening and an air outlet opening. The air inlet opening is connected to the air inlet. The airflow generator is used to generate air flow to the heat sink along an air flow path through the air outlet opening. The ion generator is located in an air flow path of the air flow between the heat sink and the airflow generator in order to produce ions.

One embodiment of the disclosure provides a heat dissipation system includes a heat sink, an airflow generator and an ion generator. The airflow generator has an air outlet opening. The airflow generator is used to generate air flow to the heat sink along an air flow path through the air outlet opening. The ion generator is located in an air flow path of the air flow between the heat sink and the airflow generator in order to produce ions.

### BRIEF DESCRIPTION OF THE DRAWINGS

The present disclosure will become more fully understood from the detailed description given hereinbelow and the accompanying drawings which are given by way of illustration only and thus are not limitative to the present disclosure and wherein:

FIG. 1 is a perspective view of an electronic device according to a first embodiment of the disclosure;

FIG. 2 is a top view of the electronic device in FIG. 1;

FIG. 3 is a schematic view showing the operation of the electronic device in FIG. 1;

FIG. 4 is a top view of a heat dissipation system of an electronic device according to a second embodiment of the disclosure; and

FIG. 5 is a cross-sectional view of a heat sink of an electronic device according to a third embodiment of the disclosure.

### DETAILED DESCRIPTION

In the following detailed description, for purposes of explanation, numerous specific details are set third in order to provide a thorough understanding of the disclosed embodiments. It will be apparent, however, that one or more embodiments may be practiced without these specific details. In other instances, well-known structures and devices are schematically shown in order to simplify the drawing.

In addition, the following embodiments are disclosed by the figures, and some practical details are described in the following paragraphs, but the present disclosure is not limited thereto. Furthermore, for the purpose of illustration, some of the structures and components in the figures are simplified, and wires, lines or buses are omitted in some of the figures.

Moreover, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

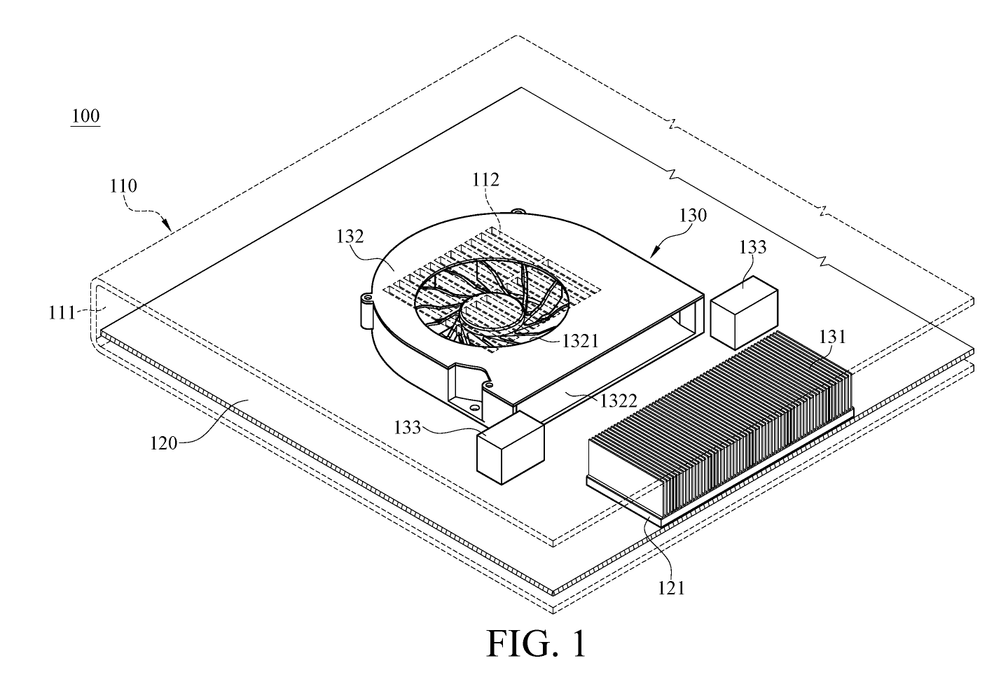

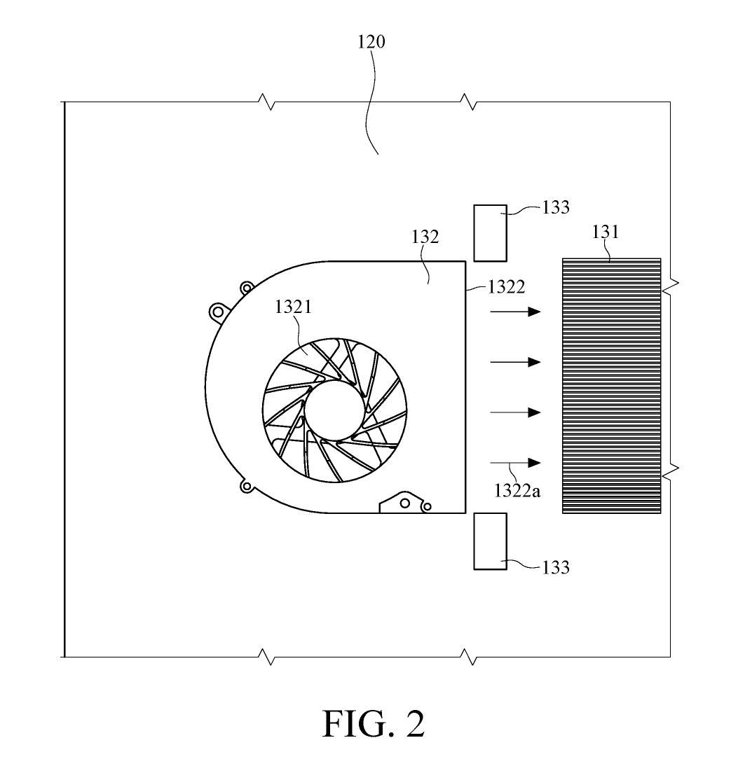

Please refer to FIG. 1 and FIG. 2. FIG. 1 is a perspective view of an electronic device according to a first embodiment of the disclosure. FIG. 2 is a top view of the electronic device in FIG. 1.

This embodiment provides an electronic device 100. The electronic device 100 includes a casing 110, an electronic module 120 and a heat dissipation system 130. The casing 110 includes an accommodating space 111 and an air inlet 112 connected to the accommodating space 111. The electronic module 120 is located in the accommodating space 111, and a heat source 121 is located on the surface of the electronic module 120.

The heat dissipation system 130 is located in the accommodating space 111. The heat dissipation system 130 includes a heat sink 131, an airflow generator 132 and an ion generator 133. The heat source 121 on the electronic module 120 is connected to the heat sink 131. The airflow generator 132 includes an air inlet opening 1321 and an air outlet opening 1322. The air inlet opening 1321 is connected to the air inlet 112. The airflow generator 132 is able to generate air flow 1322a to the heat sink 131 along an air flow 1322a path through the air outlet opening 1321. The ion generator 133 is located in the air flow path of the air flow 1322a between the heat sink 131 and the airflow generator 132 in order to produce ions. More specifically, in this embodiment, the ion generator 133 is located between the heat sink 131 and the air inlet opening 1321 of the airflow generator 132.

The air inlet 112 is disposed on the surface of the casing 110 which is located in the axial direction of the air inlet opening 1321 and close to the air inlet opening 1321, but the present disclosure is not limited thereto. In some other embodiments, the air inlet may be disposed on another surface of the casing which is located in the radial direction of the air inlet opening 1321 but still close to the air inlet opening 1321.

In addition, in this embodiment, the airflow generator 132 is a centrifugal fan, but the present disclosure is not limited thereto. In some other embodiments, the airflow generator may be an axial fan.

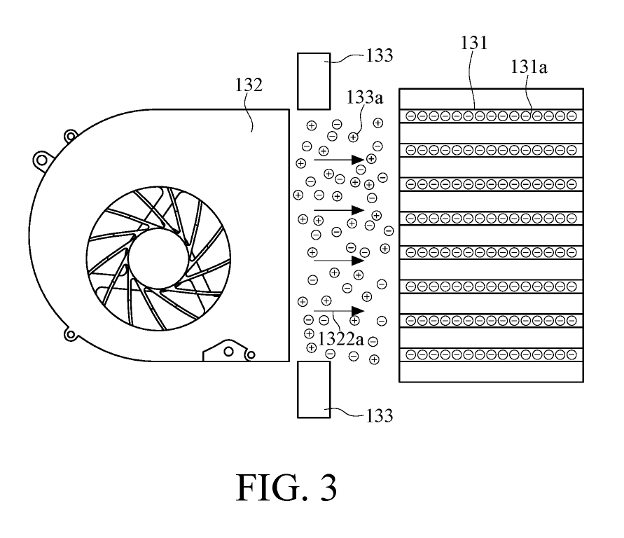

Please refer to FIG. 3, FIG. 3 is a schematic view showing the operation of the electronic device in FIG. 1. The ion generator 133 is able to produce ions 133a, and some of the ions 133a may carry positive charge or negative charge. When the airflow generator 132 operates, the dust in the air is blown to the heat sink 131, and the friction between the dust and the heat sink 131 making the dust carry positive charge and the heat sink 131 carry negative charge. On the way of the air flow 1322a to the heat sink 131, the air flow 1322a passes through the ion generator 133, and then the air flow 1322a take the negative ions and positive ions produced by the ion generator 133 to the heat sink 131 to electrically neutralize the dust having positive charge and the heat sink 131 having negative charge. As a result, the Coulomb force between the dust and the heat sink 131 is decreased, and dust is prevented from attaching to the heat sink 131.

Accordingly, in this embodiment, the electronic device 100 is able to prevent the dust in the air flow from attaching to the heat sink. In addition, the speed of the air flow 1322a is raised while the electronic device 100 is operated at a specific time, such as turning on, turning off or having high inner temperature, in order to more efficiently remove the dust attached to the heat sink 131.

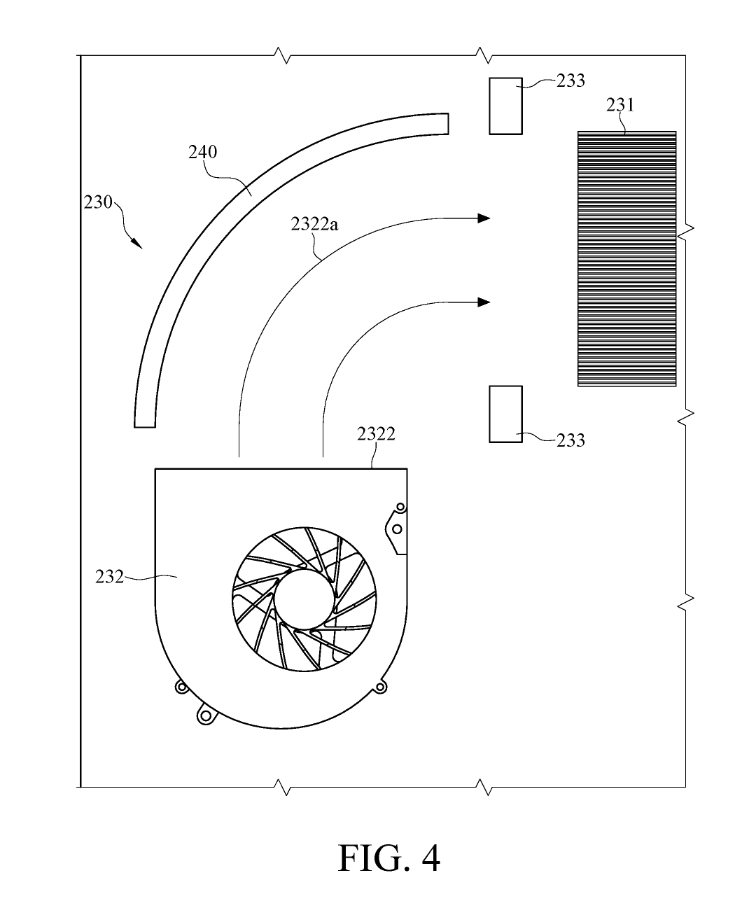

In this embodiment, the ion generator 133 of the electronic device 100 is an electrode, but the present disclosure is not limited thereto. In some other embodiments, the ion generator may be another device also capable of producing ions. In addition, in this embodiment, the ion generator 133 is located between the airflow generator 132 and the heat sink 131, but the present disclosure is not limited thereto. Please refer to FIG. 4, FIG. 4 is a top view of a heat dissipation system of an electronic device according to a second embodiment of the disclosure.

In this embodiment, a guiding plate 240 is placed in a heat dissipation system 230. The guiding plate 240 is located at the same side with an air outlet opening 2322, and an ion generator 233 is not located between the airflow generator 232 and the heat sink 231. The air flow 2322a blown by the airflow generator 232 is guided to the heat sink 231 by the guiding plate 240, and the guided air flow 2322a is able to take the positive and negative ions produced by the ion generator 233 to the heat sink 231 so as to neutralize the dust and the heat sink 231.

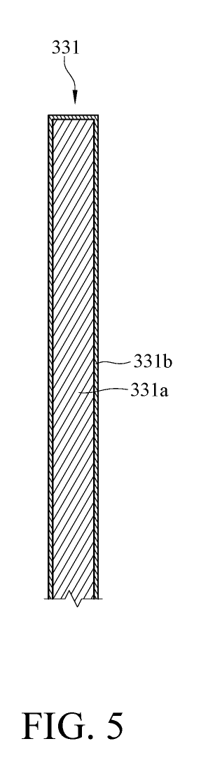

In the aforementioned embodiments, the heat sink 231 is made of electrically insulating material, such as ceramics, in order to prevent the electrostatic induction between the heat sink 231 and the dust in the air flow. However, the present disclosure is not limited to the heat sink 231. Please refer to FIG. 5, FIG. 5 is a cross-sectional view of a heat sink of an electronic device according to a third embodiment of the disclosure. In this embodiment, a heat sink 331 includes a metal layer 331a and an electrically insulating layer 331b. The electrically insulating layer 331b covers the metal layer 331a. The electrically insulating layer 331b is made of, for example, ceramics.

According to the heat dissipation system and the electronic device as discussed above, because the ion generator is located in the air flow path of the air flow between the heat sink and the airflow generator, the airflow generator is able to blow the positive and negative ions produced by the ion generator to the heat sink to electrically neutralize the dust, which has positive charge, and the heat sink, which has negative charge, thereby reducing the Coulomb force between the dust and the heat sink.

In addition, the heat sink is made of the electrically insulating material, so the heat sink is able to prevent or reduce the electrostatic induction between the dust and the heat sink. As a result, the dust in the air flow does not easily attach to the heat sink, and the speed of which dust accumulates on the heat sink is decreased so that the ability of the heat dissipation system is maintained at a desired level, and there is no longer a need to disassemble the electronic device to remove the dust attached to the heat sink

The embodiments were chosen and described in order to best explain the principles of the disclosure and its practical applications, to thereby enable others skilled in the art to best utilize the disclosure and various embodiments with various modifications as are suited to the particular use contemplated. It is intended that the scope of the disclosure be defined by the following claims and their equivalents.

What is claimed is:

1. An electronic device, comprising:
a casing having an accommodating space and an air inlet which is connected to the accommodating space;
an electronic module located in the accommodating space;
a heat sink located in the accommodating space, and the heat sink connected to the electronic module;
an airflow generator located in the accommodating space, the airflow generator having an air inlet opening and an air outlet opening, the air inlet opening connected to the air inlet, and the airflow generator used to generate air flow to the heat sink along an air flow path through the air outlet opening; and
an ion generator located in an air flow path of the air flow between the heat sink and the airflow generator in order to produce ions.

2. The electronic device according to claim 1, wherein the ion generator is located between the air outlet opening of the airflow generator and the heat sink.

3. The electronic device according to claim 1, wherein the material of the heat sink is electrically insulating.

4. The electronic device according to claim 3, wherein the material of the heat sink is ceramics.

5. The electronic device according to claim 1, wherein the heat sink includes a metal layer and an electrically insulating layer, and the metal layer is covered by the electrically insulating layer.

6. The electronic device according to claim 5, wherein the material of the electrically insulating layer is ceramics.

7. The electronic device according to claim 1, wherein the airflow generator is a centrifugal fan.

8. The electronic device according to claim 1, wherein the ion generator is an electrode.

9. A heat dissipation system, comprising:
a heat sink;
an airflow generator having an air outlet opening, and the airflow generator used to generate air flow to the heat sink along an air flow path through the air outlet opening; and
an ion generator located in an air flow path of the air flow between the heat sink and the airflow generator in order to produce ions.

10. The heat dissipation system according to claim 9, wherein the ion generator is located between the air outlet opening of the airflow generator and the heat sink.
